(19) United States
(12) Patent Application Publication
(10) Pub. No.: US 2024/0362383 A1
(43) Pub. Date: Oct. 31, 2024

(54) TIME LAPSE DATA RECONSTRUCTION AND TIME LAPSE DATA ACQUISITION SURVEY DESIGN FOR CO2 MONITORING

(71) Applicant: Schlumberger Technology Corporation, Sugar Land, TX (US)

(72) Inventors: Wenyi Hu, Fulshear, TX (US); Aria Abubakar, Sugar Land, TX (US); Haibin Di, Houston, TX (US); Zhun Li, Houston, TX (US); Cen Li, Missouri City, TX (US)

(21) Appl. No.: 18/687,114

(22) PCT Filed: Aug. 29, 2022
(86) PCT No.: PCT/US2022/041893

§ 371 Date: Feb. 27, 2024

Related U.S. Application Data
(60) Provisional application No. 63/260,629, filed on Aug. 27, 2021.

(51) Int. Cl. G06F 30/28; G06F 30/27; G06Q 50/06

(52) U.S. Cl. CPC G06F 30/28; G06F 30/27; G06Q 50/06

(57) ABSTRACT

A method for seismic surveying includes receiving a baseline dataset and a plurality of sparse monitoring datasets, generating a decimated baseline dataset by removing one or more sources, receivers, or both from the baseline dataset, generating a reconstructed baseline dataset by inputting the decimated baseline dataset into a machine learning model, generating reconstructed monitoring datasets by inputting the plurality of sparse monitoring datasets to the machine learning model, the machine learning model having been trained based on a comparison of the reconstructed baseline dataset to the baseline seismic dataset, determining accuracies for the plurality of sparse monitoring datasets by comparing the reconstructed monitoring datasets to the baseline dataset, and selecting one or more survey geometries for arranging physical sources and physical receivers in a seismic survey based at least in part on the accuracies of the plurality of sparse monitoring datasets.

### CROSS-REFERENCE TO RELATED APPLICATIONS

This application claims priority to U.S. provisional patent application having Ser. No. 63/260,629, which was filed on Aug. 27, 2021, and is incorporated herein by reference in its entirety.

### BACKGROUND

Four-dimensional (4D) time lapse seismic data is used for reservoir monitoring, CO2 injection and storage monitoring, enhanced oil recovery (EOR) monitoring, and other applications. Design and implementation of time-lapse seismic surveys can be expensive and time-consuming and inefficiencies in the design may be generated.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIGS. 1A, 1B, 1C, 1D, 2, 3A, and 3B illustrate simplified, schematic views of an oilfield and its operation, according to an embodiment.

FIG. 4 illustrates a flowchart of a method for seismic surveying, specifically sparse monitoring seismic data reconstruction as part of a seismic survey operation, according to an embodiment.

FIG. 5 illustrates an example of the source/receiver spatial distributions of a dense baseline dataset, according to an embodiment.

FIG. 6 illustrates an example of a source/receiver spatial distribution of a relatively sparse monitoring dataset, according to an embodiment.

FIG. 7 illustrates an example of shifting the baseline dataset to a grid, according to an embodiment

FIG. 8 illustrates an example of shifting the sparse monitoring dataset to a grid, according to an embodiment.

FIG. 9 illustrates an example of decimation of the baseline dataset, according to an embodiment.

FIG. 10 illustrates an example of training a machine learning model (e.g., neural network) to predict a dense dataset from a sparse dataset, according to an embodiment.

FIG. 11 illustrates implementing the neural network to generate a dense dataset from a sparse dataset, according to an embodiment.

FIG. 12 illustrates a flowchart of a method for deep-learning-based sparse monitoring dataset acquisition survey design, according to an embodiment.

FIG. 13A illustrates a source/receiver spatial distribution of a dense baseline dataset survey, and FIG. 13B illustrates a source/receiver spatial distribution of a dense monitoring dataset survey, according to an embodiment.

FIG. 14 illustrates an example of shifting a dense (baseline or monitoring) dataset to a grid, according to an embodiment.

FIG. 15 illustrates an example of decimating a dense baseline dataset, according to an embodiment.

FIG. 16 illustrates an example of training a machine learning model (e.g., neural network) to predict a dense dataset based on a sparse dataset, according to an embodiment.

FIG. 17 illustrates decimating a dense dataset to generate a plurality of sparse datasets, according to an embodiment.

FIG. 18 illustrates an example of using a machine learning model to predict a dense dataset based on a sparse dataset, and then comparing the dense dataset to a ground truth so as to determine an accuracy of the sparse dataset, according to an embodiment.

FIG. 19 illustrates selecting a sparse survey design based at least partially on reconstruction error (e.g., accuracy), according to an embodiment.

FIG. 20 illustrates a flowchart of a method for seismic surveying, specifically sparse monitoring data reconstruction within a seismic survey operation, according to an embodiment.

FIG. 21 illustrates an example of using a machine learning model to predict a sparse dataset based on dense baseline data and a sparse dataset that is missing portions, according to an embodiment.

FIG. 22 illustrates a schematic view of a computing system, according to an embodiment.

### SUMMARY

Embodiments of the disclosure include a method for seismic surveying. The method includes receiving a baseline dataset and a plurality of sparse monitoring datasets, generating a decimated baseline dataset by removing one or more sources, receivers, or both from the baseline dataset, generating a reconstructed baseline dataset by inputting the decimated baseline dataset into a machine learning model, generating reconstructed monitoring datasets by inputting the plurality of sparse monitoring datasets to the machine learning model, the machine learning model having been trained based on a comparison of the reconstructed baseline dataset to the baseline seismic dataset, determining accuracies for the plurality of sparse monitoring datasets by comparing the reconstructed monitoring datasets to the baseline dataset, and selecting one or more survey geometries for arranging physical sources and physical receivers in a seismic survey based at least in part on the accuracies of the plurality of sparse monitoring datasets.

Embodiments of the disclosure include a method for seismic surveying. The method includes receiving a baseline dataset and a monitoring dataset, generating an output image based on the baseline dataset using a machine learning model, generating a selected output by removing one or more traces from the output image, determining a loss function by comparing the selected output with the monitoring dataset, adjusting the machine learning model based at least in part on the loss function, and reconstructing an interpolated monitoring dataset based on the monitoring dataset using the machine learning model.

Embodiments of the disclosure include a method for seismic surveying. The method includes receiving a monitoring dataset and a baseline dataset, generating an output based on the baseline dataset using a first machine learning model, generating a selected output by removing one or more traces from the output, determining a loss function by comparing the selected output with the monitoring dataset, adjusting the first machine learning model based at least in part on the loss function, reconstructing an interpolated monitoring dataset based on the monitoring dataset using the first machine learning model, receiving a plurality of sparse monitoring datasets, the plurality of sparse monitoring datasets having been generated based at least in part on the interpolated monitoring dataset, generating a decimated baseline dataset by removing one or more sources, receivers, or both from the baseline dataset, generating a reconstructed baseline dataset by inputting the decimated baseline dataset into a second machine learning model, generating reconstructed monitoring datasets by inputting the plurality of sparse monitoring datasets to the second machine learning model, the second machine learning model having been trained based at least in part on a comparison of the reconstructed baseline dataset to the baseline seismic dataset, determining accuracies for the plurality of sparse monitoring datasets by comparing the reconstructed monitoring datasets to the baseline dataset, and selecting one or more survey geometries for arranging physical sources and physical receivers in a seismic survey based at least in part on the accuracies of the plurality of sparse monitoring datasets.

Thus, the computing systems and methods disclosed herein are more effective methods for processing collected data that may, for example, correspond to a surface and a subsurface region. These computing systems and methods increase data processing effectiveness, efficiency, and accuracy. Such methods and computing systems may complement or replace conventional methods for processing collected data. This summary is provided to introduce a selection of concepts that are further described below in the detailed description. This summary is not intended to identify key or essential features of the claimed subject matter, nor is it intended to be used as an aid in limiting the scope of the claimed subject matter.

### DESCRIPTION OF EMBODIMENTS

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object could be termed a second object, and, similarly, a second object could be termed a first object, without departing from the scope of the invention. The first object and the second object are both objects, respectively, but they are not to be considered the same object.

The terminology used in the description of the invention herein is for the purpose of describing particular embodiments only and is not intended to be limiting of the invention. As used in the description of the invention and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques and workflows that are in accordance with some embodiments. Some operations in the processing procedures, methods, techniques and workflows disclosed herein may be combined and/or the order of some operations may be changed.

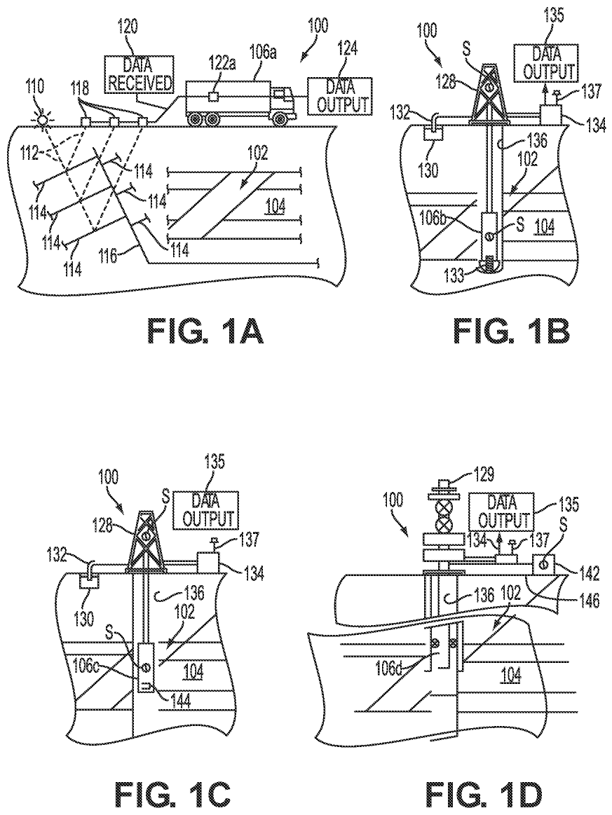

FIGS. 1A-1D illustrate simplified, schematic views of oilfield 100 having subterranean formation 102 containing reservoir 104 therein in accordance with implementations of various technologies and techniques described herein. FIG. 1A illustrates a survey operation being performed by a survey tool, such as seismic truck 106a, to measure properties of the subterranean formation. The survey operation is a seismic survey operation for producing sound vibrations. In FIG. 1A, one such sound vibration, e.g., sound vibration 112 generated by source 110, reflects off horizons 114 in earth formation 116. A set of sound vibrations is received by sensors, such as geophone-receivers 118, situated on the earth's surface. The data received 120 is provided as input data to a computer 122a of a seismic truck 106a, and responsive to the input data, computer 122a generates seismic data output 124. This seismic data output may be stored, transmitted or further processed as desired, for example, by data reduction.

FIG. 1B illustrates a drilling operation being performed by drilling tools 106b suspended by rig 128 and advanced into subterranean formations 102 to form wellbore 136. Mud pit 130 is used to draw drilling mud into the drilling tools via flow line 132 for circulating drilling mud down through the drilling tools, then up wellbore 136 and back to the surface. The drilling mud is typically filtered and returned to the mud pit. A circulating system may be used for storing, controlling, or filtering the flowing drilling mud. The drilling tools are advanced into subterranean formations 102 to reach reservoir 104. Each well may target one or more reservoirs. The drilling tools are adapted for measuring downhole properties using logging while drilling tools. The logging while drilling tools may also be adapted for taking core sample 133 as shown.

Computer facilities may be positioned at various locations about the oilfield 100 (e.g., the surface unit 134) and/or at remote locations. Surface unit 134 may be used to communicate with the drilling tools and/or offsite operations, as well as with other surface or downhole sensors. Surface unit 134 is capable of communicating with the drilling tools to send commands to the drilling tools, and to receive data therefrom. Surface unit 134 may also collect data generated during the drilling operation and produce data output 135, which may then be stored or transmitted.

Sensors(S), such as gauges, may be positioned about oilfield 100 to collect data relating to various oilfield operations as described previously. As shown, sensor(S) is positioned in one or more locations in the drilling tools and/or at rig 128 to measure drilling parameters, such as weight on bit, torque on bit, pressures, temperatures, flow rates, compositions, rotary speed, and/or other parameters of the field operation. Sensors(S) may also be positioned in one or more locations in the circulating system.

Drilling tools 106b may include a bottom hole assembly (BHA) (not shown), generally referenced, near the drill bit (e.g., within several drill collar lengths from the drill bit). The bottom hole assembly includes capabilities for measuring, processing, and storing information, as well as communicating with surface unit 134. The bottom hole assembly further includes drill collars for performing various other measurement functions.

The bottom hole assembly may include a communication subassembly that communicates with surface unit 134. The communication subassembly is adapted to send signals to and receive signals from the surface using a communications channel such as mud pulse telemetry, electro-magnetic telemetry, or wired drill pipe communications. The communication subassembly may include, for example, a transmitter that generates a signal, such as an acoustic or electromagnetic signal, which is representative of the measured drilling parameters. It will be appreciated by one of skill in the art that a variety of telemetry systems may be employed, such as wired drill pipe, electromagnetic or other known telemetry systems.

Typically, the wellbore is drilled according to a drilling plan that is established prior to drilling. The drilling plan typically sets forth equipment, pressures, trajectories and/or other parameters that define the drilling process for the wellsite. The drilling operation may then be performed according to the drilling plan. However, as information is gathered, the drilling operation may need to deviate from the drilling plan. Additionally, as drilling or other operations are performed, the subsurface conditions may change. The earth model may also need adjustment as new information is collected

The data gathered by sensors (S) may be collected by surface unit 134 and/or other data collection sources for analysis or other processing. The data collected by sensors (S) may be used alone or in combination with other data. The data may be collected in one or more databases and/or transmitted on or offsite. The data may be historical data, real time data, or combinations thereof. The real time data may be used in real time, or stored for later use. The data may also be combined with historical data or other inputs for further analysis. The data may be stored in separate databases, or combined into a single database.

Surface unit 134 may include transceiver 137 to allow communications between surface unit 134 and various portions of the oilfield 100 or other locations. Surface unit 134 may also be provided with or functionally connected to one or more controllers (not shown) for actuating mechanisms at oilfield 100. Surface unit 134 may then send command signals to oilfield 100 in response to data received. Surface unit 134 may receive commands via transceiver 137 or may itself execute commands to the controller. A processor may be provided to analyze the data (locally or remotely), make the decisions and/or actuate the controller. In this manner, oilfield 100 may be selectively adjusted based on the data collected. This technique may be used to optimize (or improve) portions of the field operation, such as controlling drilling, weight on bit, pump rates, or other parameters. These adjustments may be made automatically based on computer protocol, and/or manually by an operator. In some cases, well plans may be adjusted to select optimum (or improved) operating conditions, or to avoid problems.

FIG. 1C illustrates a wireline operation being performed by wireline tool 106c suspended by rig 128 and into wellbore 136 of FIG. 1B. Wireline tool 106c is adapted for deployment into wellbore 136 for generating well logs, performing downhole tests and/or collecting samples. Wireline tool 106c may be used to provide another method and apparatus for performing a seismic survey operation. Wireline tool 106c may, for example, have an explosive, radioactive, electrical, or acoustic energy source 144 that sends and/or receives electrical signals to surrounding subterranean formations 102 and fluids therein.

Wireline tool 106c may be operatively connected to, for example, geophones 118 and a computer 122a of a seismic truck 106a of FIG. 1A. Wireline tool 106c may also provide data to surface unit 134. Surface unit 134 may collect data generated during the wireline operation and may produce data output 135 that may be stored or transmitted. Wireline tool 106c may be positioned at various depths in the wellbore 136 to provide a survey or other information relating to the subterranean formation 102.

Sensors (S), such as gauges, may be positioned about oilfield 100 to collect data relating to various field operations as described previously. As shown, sensor S is positioned in wireline tool 106c to measure downhole parameters which relate to, for example porosity, permeability, fluid composition and/or other parameters of the field operation.

FIG. 1D illustrates a production operation being performed by production tool 106d deployed from a production unit or Christmas tree 129 and into completed wellbore 136 for drawing fluid from the downhole reservoirs into surface facilities 142. The fluid flows from reservoir 104 through perforations in the casing (not shown) and into production tool 106d in wellbore 136 and to surface facilities 142 via gathering network 146.

Sensors (S), such as gauges, may be positioned about oilfield 100 to collect data relating to various field operations as described previously. As shown, the sensor (S) may be positioned in production tool 106d or associated equipment, such as Christmas tree 129, gathering network 146, surface facility 142, and/or the production facility, to measure fluid parameters, such as fluid composition, flow rates, pressures, temperatures, and/or other parameters of the production operation.

Production may also include injection wells for added recovery. One or more gathering facilities may be operatively connected to one or more of the wellsites for selectively collecting downhole fluids from the wellsite(s).

While FIGS. 1B-1D illustrate tools used to measure properties of an oilfield, it will be appreciated that the tools may be used in connection with non-oilfield operations, such as gas fields, mines, aquifers, storage or other subterranean facilities. Also, while certain data acquisition tools are depicted, it will be appreciated that various measurement tools capable of sensing parameters, such as seismic two-way travel time, density, resistivity, production rate, etc., of the subterranean formation and/or its geological formations may be used. Various sensors (S) may be located at various positions along the wellbore and/or the monitoring tools to collect and/or monitor the desired data. Other sources of data may also be provided from offsite locations.

The field configurations of FIGS. 1A-1D are intended to provide a brief description of an example of a field usable with oilfield application frameworks. Part of, or the entirety, of oilfield 100 may be on land, water and/or sea. Also, while a single field measured at a single location is depicted, oilfield applications may be utilized with any combination of one or more oilfields, one or more processing facilities and one or more wellsites.

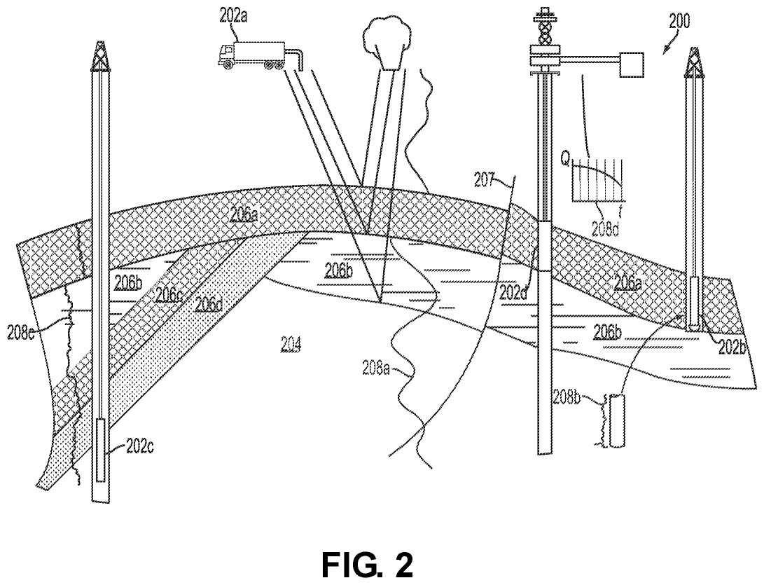

FIG. 2 illustrates a schematic view, partially in cross section of oilfield 200 having data acquisition tools 202a, 202b, 202c and 202d positioned at various locations along oilfield 200 for collecting data of subterranean formation 204 in accordance with implementations of various technologies and techniques described herein. Data acquisition tools 202a-202d may be the same as data acquisition tools 106a-106d of FIGS. 1A-1D, respectively, or others not depicted. As shown, data acquisition tools 202a-202d generate data plots or measurements 208a-208d, respectively. These data plots are depicted along oilfield 200 to demonstrate the data generated by the various operations.

Data plots 208a-208c are examples of static data plots that may be generated by data acquisition tools 202a-202c, respectively; however, it should be understood that data plots 208a-208c may also be data plots that are updated in real time. These measurements may be analyzed to better define the properties of the formation(s) and/or determine the accuracy of the measurements and/or for checking for errors. The plots of each of the respective measurements may be aligned and scaled for comparison and verification of the properties.

Static data plot 208a is a seismic two-way response over a period of time. Static plot 208b is core sample data measured from a core sample of the formation 204. The core sample may be used to provide data, such as a graph of the density, porosity, permeability, or some other physical property of the core sample over the length of the core. Tests for density and viscosity may be performed on the fluids in the core at varying pressures and temperatures. Static data plot 208c is a logging trace that typically provides a resistivity or other measurement of the formation at various depths.

A production decline curve or graph 208d is a dynamic data plot of the fluid flow rate over time. The production decline curve typically provides the production rate as a function of time. As the fluid flows through the wellbore, measurements are taken of fluid properties, such as flow rates, pressures, composition, etc.

Other data may also be collected, such as historical data, user inputs, economic information, and/or other measurement data and other parameters of interest. As described below, the static and dynamic measurements may be analyzed and used to generate models of the subterranean formation to determine characteristics thereof. Similar measurements may also be used to measure changes in formation aspects over time.

The subterranean structure 204 has a plurality of geological formations 206a-206d. As shown, this structure has several formations or layers, including a shale layer 206a, a carbonate layer 206b, a shale layer 206c and a sand layer 206d. A fault 207 extends through the shale layer 206a and the carbonate layer 206b. The static data acquisition tools are adapted to take measurements and detect characteristics of the formations.

While a specific subterranean formation with specific geological structures is depicted, it will be appreciated that oilfield 200 may contain a variety of geological structures and/or formations, sometimes having extreme complexity. In some locations, typically below the water line, fluid may occupy pore spaces of the formations. Each of the measurement devices may be used to measure properties of the formations and/or its geological features. While each acquisition tool is shown as being in specific locations in oilfield 200, it will be appreciated that one or more types of measurement may be taken at one or more locations across one or more fields or other locations for comparison and/or analysis.

The data collected from various sources, such as the data acquisition tools of FIG. 2, may then be processed and/or evaluated. Typically, seismic data displayed in static data plot 208a from data acquisition tool 202a is used by a geophysicist to determine characteristics of the subterranean formations and features. The core data shown in static plot 208b and/or log data from well log 208c are typically used by a geologist to determine various characteristics of the subterranean formation. The production data from graph 208d is typically used by the reservoir engineer to determine fluid flow reservoir characteristics. The data analyzed by the geologist, geophysicist and the reservoir engineer may be analyzed using modeling techniques.

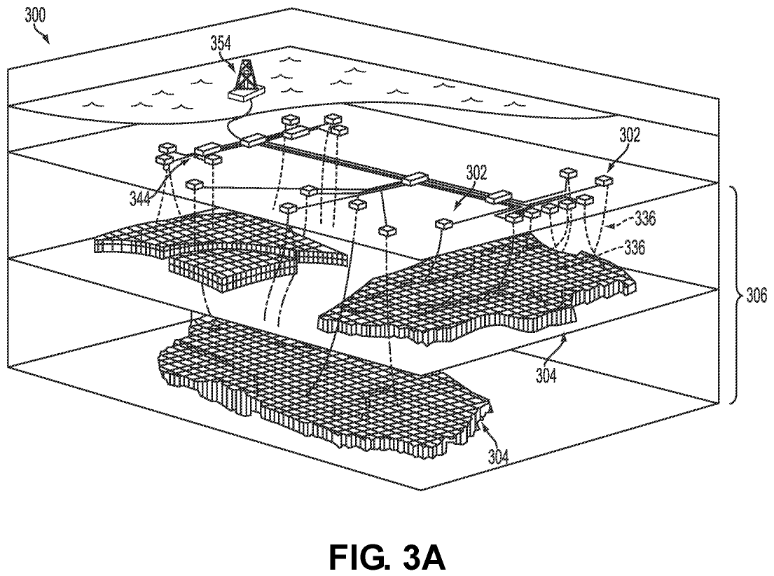

FIG. 3A illustrates an oilfield 300 for performing production operations in accordance with implementations of various technologies and techniques described herein. As shown, the oilfield has a plurality of wellsites 302 operatively connected to central processing facility 354. The oilfield configuration of FIG. 3A is not intended to limit the scope of the oilfield application system. Part, or all, of the oilfield may be on land and/or sea. Also, while a single oilfield with a single processing facility and a plurality of wellsites is depicted, any combination of one or more oilfields, one or more processing facilities and one or more wellsites may be present.

Each wellsite 302 has equipment that forms wellbore 336 into the earth. The wellbores extend through subterranean formations 306 including reservoirs 304. These reservoirs 304 contain fluids, such as hydrocarbons. The wellsites draw fluid from the reservoirs and pass them to the processing facilities via surface networks 344. The surface networks 344 have tubing and control mechanisms for controlling the flow of fluids from the wellsite to processing facility 354.

Attention is now directed to FIG. 3B, which illustrates a side view of a marine-based survey 360 of a subterranean subsurface 362 in accordance with one or more implementations of various techniques described herein. Subsurface 362 includes seafloor surface 364. Seismic sources 366 may include marine sources such as vibroseis or airguns, which may propagate seismic waves 368 (e.g., energy signals) into the Earth over an extended period of time or at a nearly instantaneous energy provided by impulsive sources. The seismic waves may be propagated by marine sources as a frequency sweep signal. For example, marine sources of the vibroseis type may initially emit a seismic wave at a low frequency (e.g., 5 Hz) and increase the seismic wave to a high frequency (e.g., 80-90 Hz) over time.

The component(s) of the seismic waves 368 may be reflected and converted by seafloor surface 364 (i.e., reflector), and seismic wave reflections 370 may be received by a plurality of seismic receivers 372. Seismic receivers 372 may be disposed on a plurality of streamers (i.e., streamer array 374). The seismic receivers 372 may generate electrical signals representative of the received seismic wave reflections 370. The electrical signals may be embedded with information regarding the subsurface 362 and captured as a record of seismic data.

In one implementation, each streamer may include streamer steering devices such as a bird, a deflector, a tail buoy and the like, which are not illustrated in this application. The streamer steering devices may be used to control the position of the streamers in accordance with the techniques described herein.

In one implementation, seismic wave reflections 370 may travel upward and reach the water/air interface at the water surface 376, a portion of reflections 370 may then reflect downward again (i.e., sea-surface ghost waves 378) and be received by the plurality of seismic receivers 372. The sea-surface ghost waves 378 may be referred to as surface multiples. The point on the water surface 376 at which the wave is reflected downward is generally referred to as the downward reflection point.

The electrical signals may be transmitted to a vessel 380 via transmission cables, wireless communication or the like. The vessel 380 may then transmit the electrical signals to a data processing center. Alternatively, the vessel 380 may include an onboard computer capable of processing the electrical signals (i.e., seismic data). Those skilled in the art having the benefit of this disclosure will appreciate that this illustration is highly idealized. For instance, surveys may be of formations deep beneath the surface. The formations may typically include multiple reflectors, some of which may include dipping events, and may generate multiple reflections (including wave conversion) for receipt by the seismic receivers 372. In one implementation, the seismic data may be processed to generate a seismic image of the subsurface 362.

Marine seismic acquisition systems tow each streamer in streamer array 374 at the same depth (e.g., 5-10 m). However, marine based survey 360 may tow each streamer in streamer array 374 at different depths such that seismic data may be acquired and processed in a manner that avoids the effects of destructive interference due to sea-surface ghost waves. For instance, marine-based survey 360 of FIG. 3B illustrates eight streamers towed by vessel 380 at eight different depths. The depth of each streamer may be controlled and maintained using the birds disposed on each streamer.

Embodiments of the present disclosure may include deep-learning-based workflows to reduce the cost of time lapse monitoring seismic data acquisition, including reconstruction of sparsely acquired monitoring dataset and sparse monitoring dataset acquisition design. In some embodiments, the present methods may reduce seismic acquisition cost while maintaining data quality and without losing subsurface information. In addition, the functionality may be used to obtain monitoring datasets as dense as measured baseline datasets, which may be from sparsely acquired monitoring datasets. Embodiments of the present disclosure may also apply to non-seismic measurements, such as controlled source electromagnetic surveys (CSEMs). The acquisition cost reduction may be achieved by sparse monitoring survey design that reduces the number of sources and receivers in the survey, constructs acquired monitoring dataset to the original source and receiver locations using deep learning and recommends source and receiver number and deployment. The cost savings may be determined, for example, by a ratio of dense source and receiver number to sparse source and receiver number.

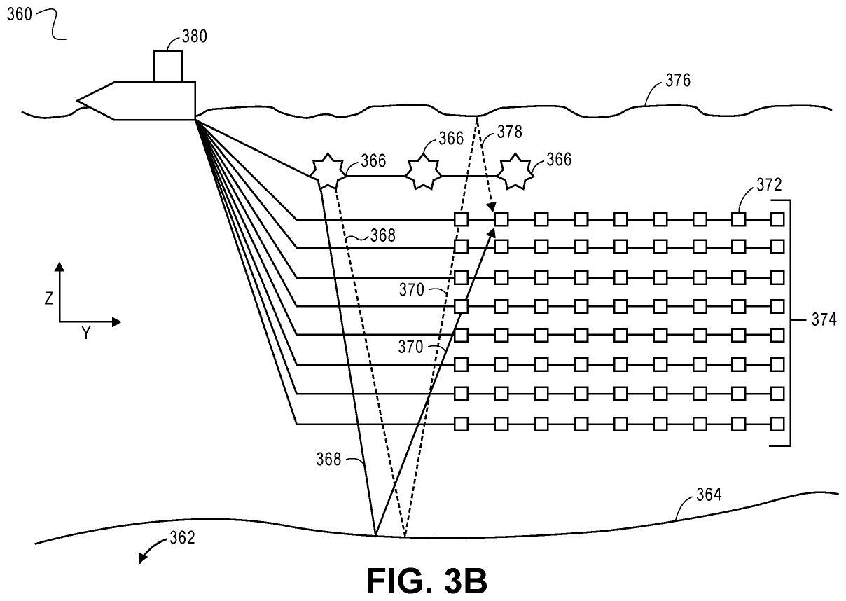

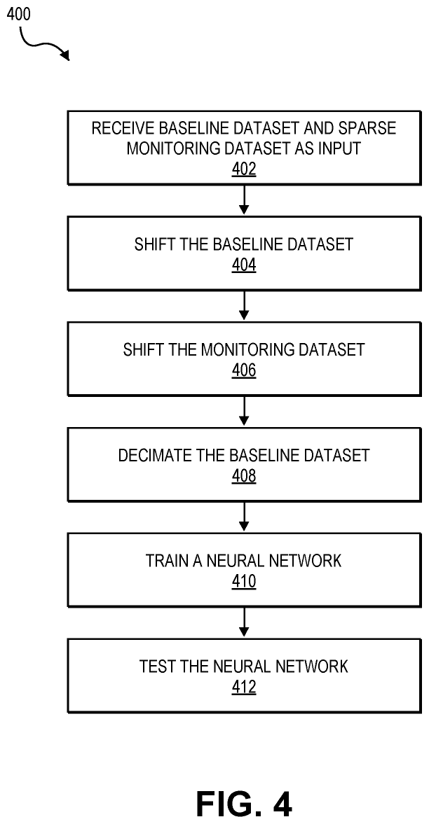

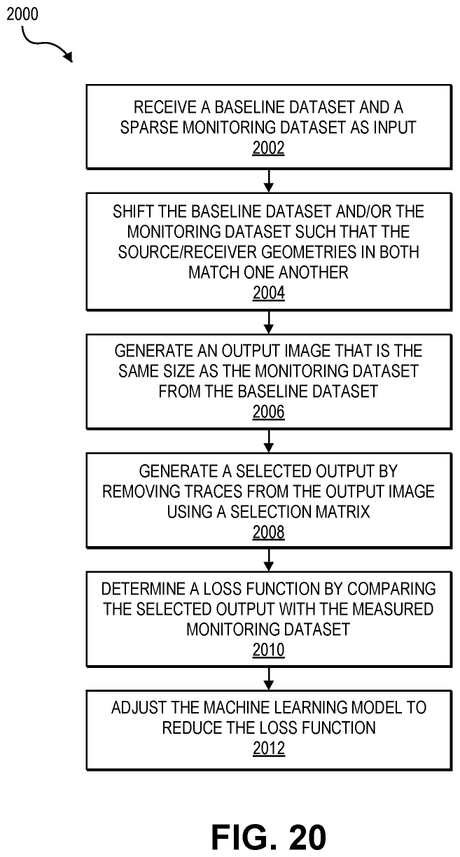

FIG. 4 illustrates a flowchart of a method 400 for seismic surveying, specifically sparse monitoring seismic data reconstruction as part of a seismic survey operation, according to an embodiment. The method 400 may implement a deep-learning workflow, as mentioned above. Specifically, the method 400 may include receiving, as input, a baseline dataset and one or more “sparse” monitoring datasets, as at 402. In at least some embodiments, the sparse monitoring datasets may be reconstructed monitoring datasets generated by the method 2000 of FIG. 20, discussed below. The datasets may be acquired via a seismic survey and/or through synthetic generation of seismic data based on a geophysical model of the subsurface. The baseline dataset may be dense compared to the monitoring datasets, as will be described in greater detail below. FIG. 5 illustrates an example of a baseline dataset 500, which may be a dense dataset from a seismic survey, according to an embodiment. The baseline dataset 500 may be populated with receivers and sources, which are indicated by dots 502. As can be appreciated, the dots 502 may not be uniformly distributed within the baseline dataset 500.

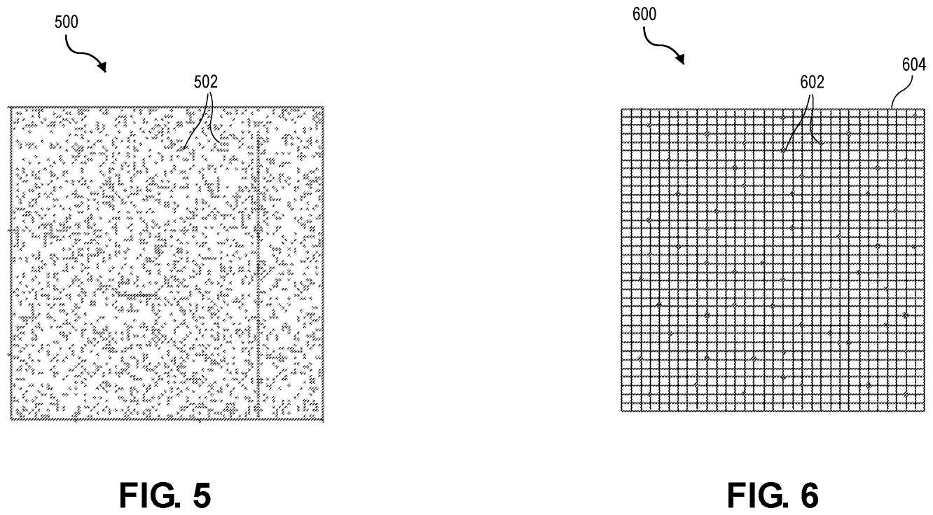

FIG. 6 illustrates an example of a sparse monitoring dataset 600, according to an embodiment. The sparse monitoring dataset 600 may include sources/receivers, represented by dots 602, which may be distributed, although potentially not with uniform density/spacing, along a grid 654. Comparing the baseline dataset 500 of FIG. 5 and the sparse monitoring dataset 600 of FIG. 6, it may be seen that the baseline dataset 500 of FIG. 5 is more densely populated with sources/receivers (dots 502 of FIG. 5) than is the sparse monitoring survey data 600 of FIG. 6 with dots 602 of FIG. 6. Accordingly, “dense” and “sparse” are relative terms that refer to the number of survey data points in a given area, with dense datasets having more data points in a given area than a sparse dataset.

Referring again to FIG. 4, the method 400 may then include shifting the baseline dataset, as at 404. In some embodiments, sources and receivers for the seismic data acquisition survey that generate and acquire the seismic waves that make up the baseline dataset are not located on uniform grids. For example, the sources and receivers of the dense baseline dataset may be deployed randomly on the earth surface or in any convenient manner. Accordingly, the sources and receivers are shifted to the uniform grid mathematically, thereby shifting the baseline dataset at 404.

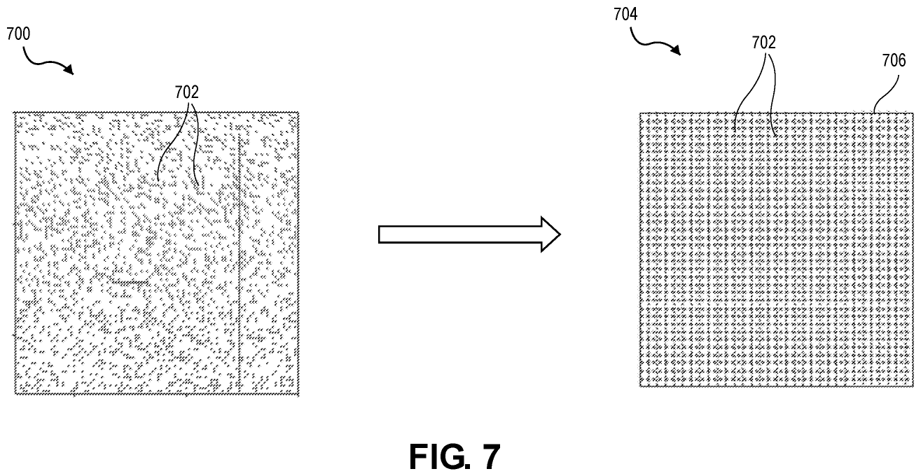

FIG. 7 illustrates an example of shifting the sources and receivers in a dense baseline dataset, according to an embodiment. In particular, a non-uniform distribution of sources and receivers are indicated as dots 702 within an area 700. In area 704, a grid 706 has been implemented, as shown on the right side of FIG. 7, with the sources and receivers still represented as dots 702, but the dots 702 now being aligned according to the grid 706 (e.g., placed on a corner of the grid 706). It is noted that the physical receivers and sources that produce the survey data may not be moved, but rather the data generated by the sources and receivers is adjusted mathematically to what would have been observed if the sources/receivers had been on the grid 706. To implement this shifting, various different techniques can be used, such as nearest neighbor interpolation, linear interpolation, Lagrange interpolation, B-spline interpolation, Sinc interpolation, and many others.

Referring again to FIG. 4, the method 400 may also include shifting the sparse monitoring dataset, as at 406. The sources and receivers of the sparsely acquired monitoring dataset may be shifted to the uniform grid mathematically so that the shifted (or “regularized”) monitoring dataset and the shifted baseline dataset use the same grid system.

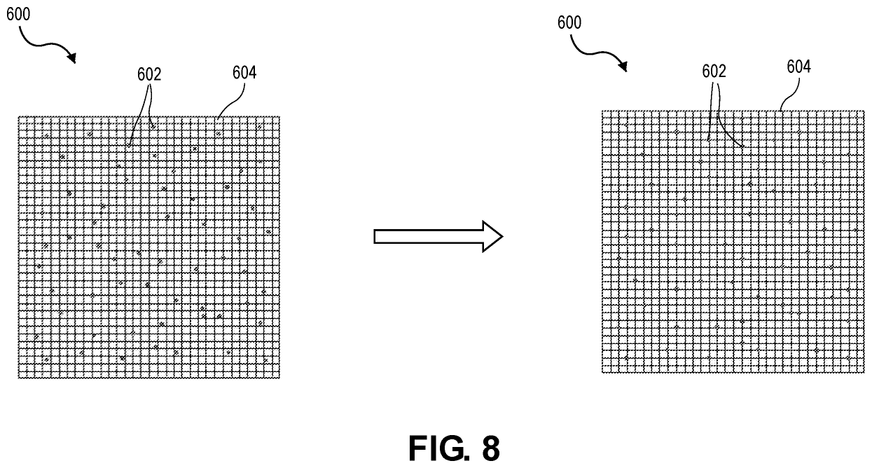

FIG. 8 illustrates an example of shifting sources and receivers in a sparse monitoring dataset, according to an embodiment. In particular, the sparse monitoring dataset 600 of FIG. 6 is shown on the left side of FIG. 8. The monitoring dataset 600 may include the dots 602 representing the sources and receivers, which may, initially, not coincide with the grid 604. Proceeding to the right side of FIG. 8, the dots 602 may be moved (shifted) by mathematical interpolation (as discussed above), such that they are represented as aligned with (e.g., located on corners of) the grid 604.

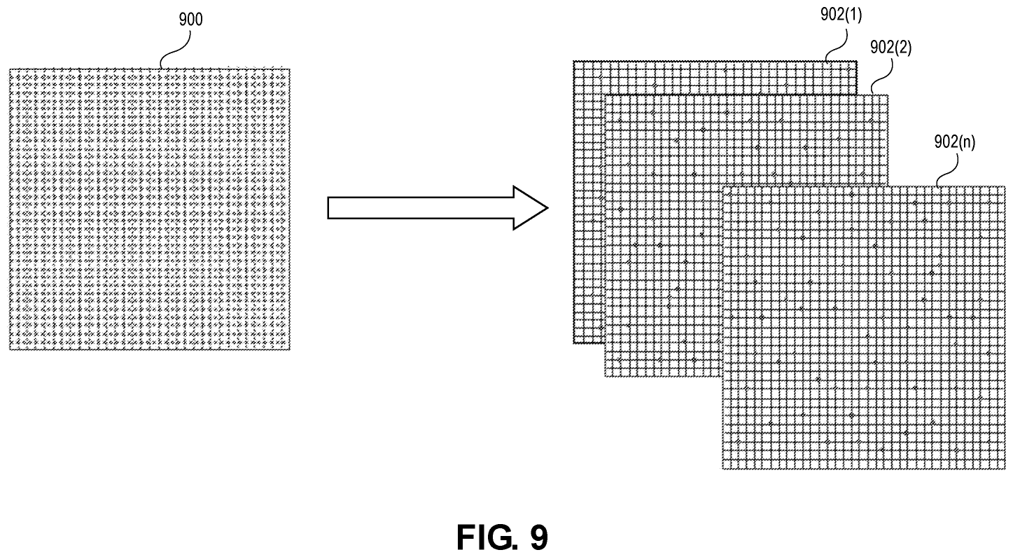

Returning to FIG. 4, the method 400 may further include decimating the baseline dataset, as at 408. For example, one or more sources, receivers, or both may be removed from consideration (e.g., randomly or using a source/receiver dropping scheme) in the shifted baseline dataset to generate multiple sparse survey geometries. FIG. 9 illustrates a conceptual view of generating multiple sparse survey geometries, according to an embodiment. In this simplified example, a single (e.g., dense) baseline dataset 900 is provided. By removing different sets of sources and/or receivers, many different decimated data sets 902(1), 902(2), . . . , 902(n) may be produced, each with fewer sources and receivers than the baseline dataset 900. For example, the number of sources and/or receivers removed may be selected so that the remaining number of sources and/or receivers matches the sparse monitoring dataset. Thus, potentially many training pairs may be developed as the data from the complete baseline dataset, and the data from the decimated based line data, providing labels for a neural network or another machine learning model, as will be described in greater detail below.

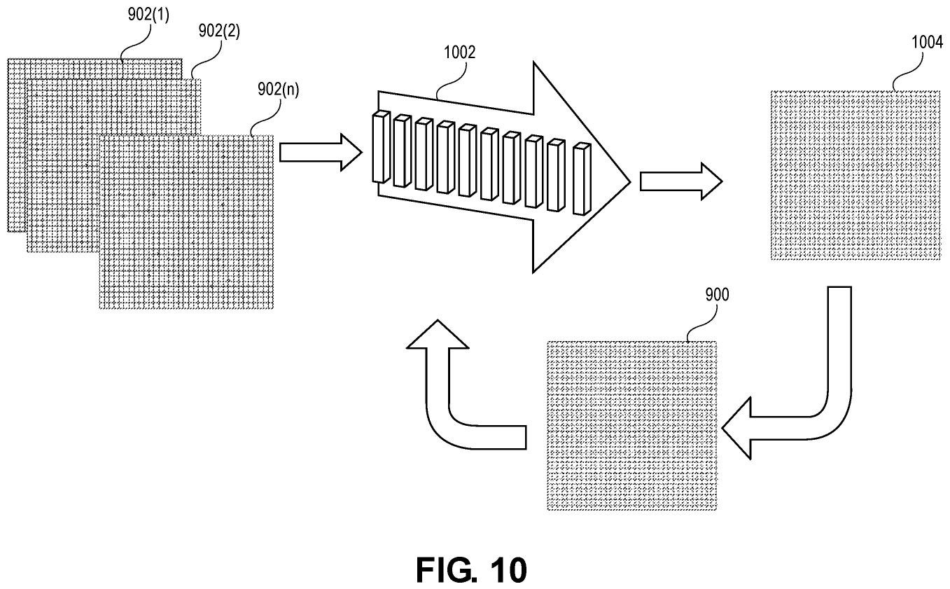

Referring again to FIG. 4, next, the method 400 may proceed to training a machine learning model, such as a neural network (e.g., a convolutional neural network) using the training pairs, as at 410. FIG. 10 illustrates a conceptual view of this training process, according to an embodiment. As shown, the decimated baseline datasets 902(1), 902(2), . . . , 902(n) may be inputted into a neural network (NN) 1002 or any other type of machine learning model. The output of the NN 1002 is a reconstructed dataset 1004 having a same density (and thus, at an equivalent area, the same number of sources/receivers) as the baseline dataset 900 from which the decimated data sets 902(1), 902(2), . . . , 902(n) were constructed, as discussed above. The reconstructed dataset 1004 may then be compared with the baseline dataset 900 (e.g., the “ground truth”), and the difference therebetween (“residual”), may be used to construct a loss function. The loss function may be fed back (e.g., back-propagated) to the NN 1002 to update parameters (e.g., weights) of the NN 1002. This procedure (using the NN 1002 to generate the reconstructed dataset 1004, and then generating a loss function by comparing the reconstructed dataset 1004 with the baseline dataset 900) may be repeated until the NN 1002 is considered fully trained (e.g., until the loss function value is reduced to a certain level or the loss function value does not decrease anymore).

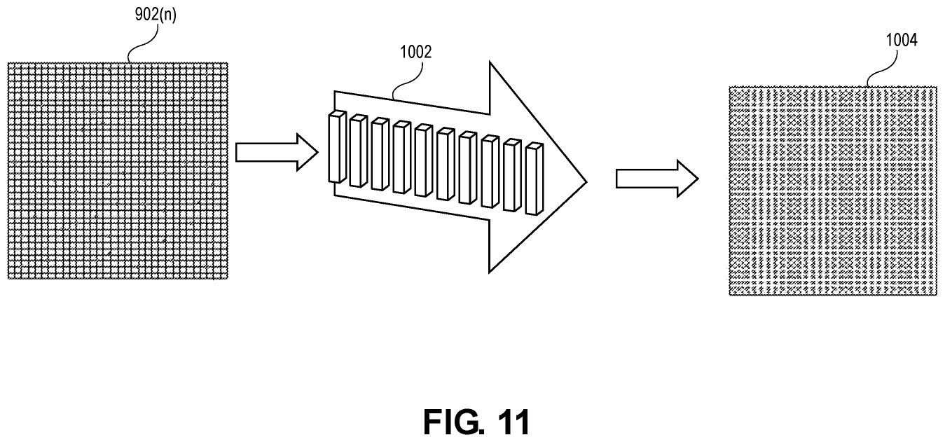

Returning to FIG. 4, the machine learning model (e.g., NN 1004 of FIG. 10) may then be tested, as at 412. For example, as shown in FIG. 11, a sparse monitoring dataset 902(n), e.g., one not used to train the NN 1002, may be inputted into the fully trained NN 1002 to reconstruct the dense monitoring dataset 1004. The reconstructed dense monitoring dataset 1004 may then be compared to original dense monitoring dataset 900 (e.g., FIG. 9), in order to establish the residual and determine if the NN 1004 produced a sufficiently accurate reconstructed dataset 1004 based on the residual. It will be appreciated that, if the original, input dataset is sparse, a residual may not be calculated, as a comparison with a dense dataset may not be available.

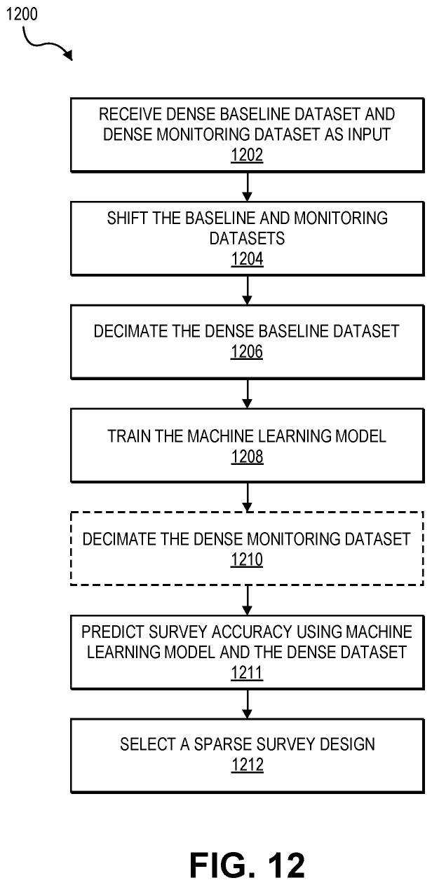

Referring now to FIG. 12, there is shown a flowchart of a method 1200 for deep-learning-based sparse monitoring dataset acquisition survey design, according to an embodiment. The method 1200 may include receiving baseline dataset and monitoring dataset, e.g., dense baseline dataset and dense monitoring dataset, as at 1202.

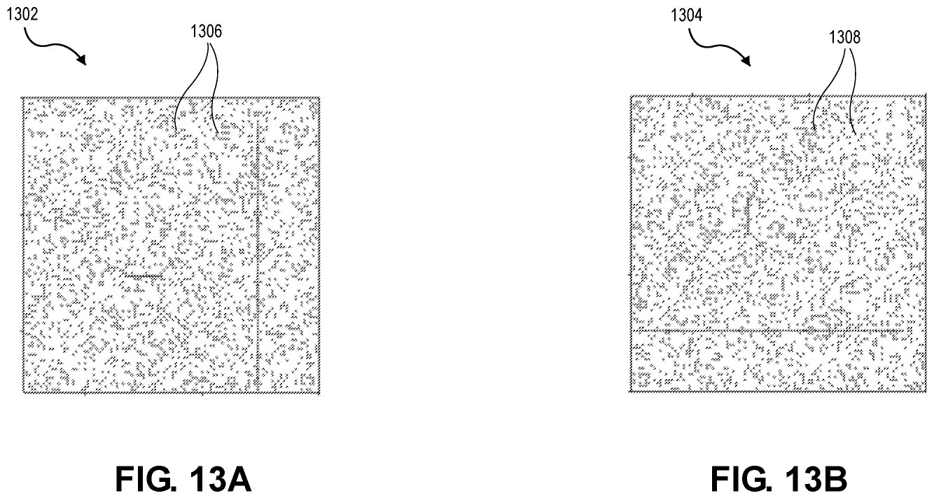

FIG. 13 illustrates the baseline dataset 1302 and monitoring dataset 1304, according to an embodiment. As can be seen, the baseline dataset 1302 and the monitoring dataset 1304 may both be relatively dense (e.g., as compared to the sparse monitoring dataset 600 of FIG. 6). For example, there may be approximately the same number of sources and receivers of the baseline dataset 1302, represented by dots 1306, as of the monitoring dataset 1304, represented by dots 1308.

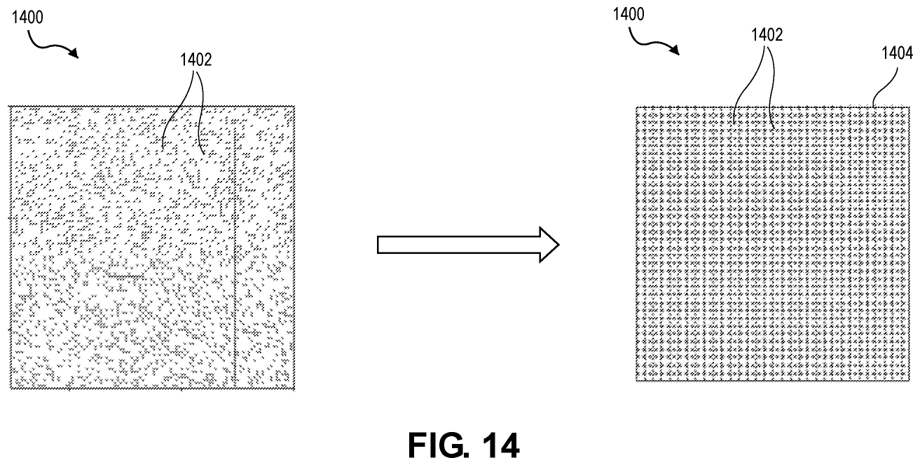

The method 1200 may include shifting the baseline dataset and monitoring dataset, as at 1204. FIG. 14 illustrates an example of shifting the baseline dataset, which may apply to the monitoring dataset as well. For example, baseline dataset 1400 may include sources and receivers, represented by dots 1402. The dots 1402 are initially randomly or otherwise dispersed in a non-uniform manner. A shifting or “regularization” scheme, such as those discussed above, may then be applied to mathematically “move” the sources and receivers, represented by the dots 1402, to corners of a grid 1404, as shown on the right side of FIG. 14. As noted above, the sources/receivers may not be physically moved, but rather the data generated thereby in the survey adjusted to what would have been provided if they were distributed according to the grid 1404. The same or a similar procedure may be applied to the dense monitoring dataset.

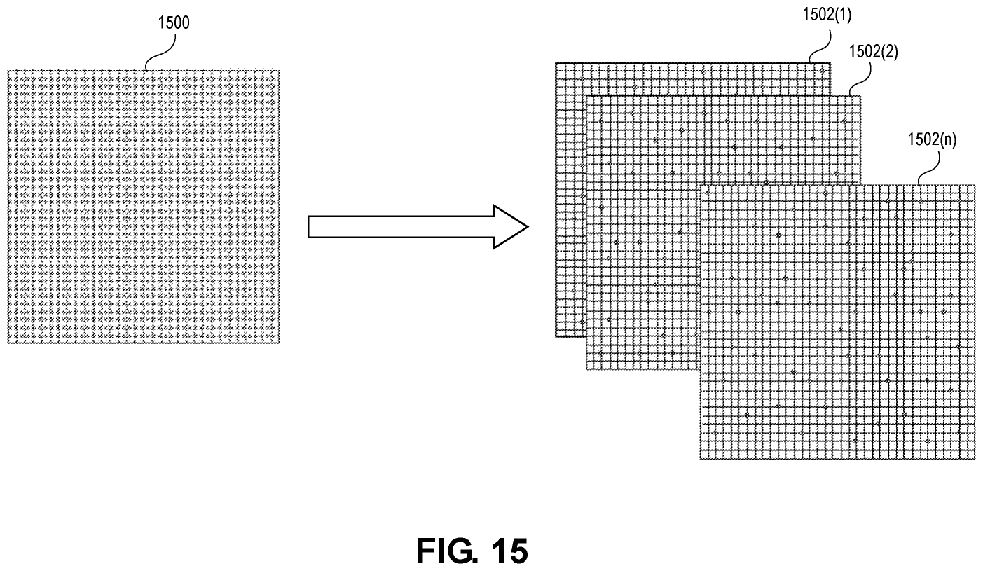

Referring back to FIG. 12, the dense baseline dataset may then be decimated, as at 1206. FIG. 15 illustrates a conceptual view of such decimation, according to an embodiment. As shown, dense baseline dataset 1500 may be received. Sources and receivers present in the dense baseline dataset 1500 may then be removed (e.g., randomly or according to a predefined scheme) therefrom to generate multiple sparse survey geometries, e.g., decimated baseline dataset 1502(1), 1502(2), . . . , 1502(n). The pair of complete, shifted baseline dataset 1500 and the decimated, shifted baseline dataset 1502(1), 1502(2), . . . , 1502(n) serve as labeled training pairs for neural network (or any other type of machine learning) training.

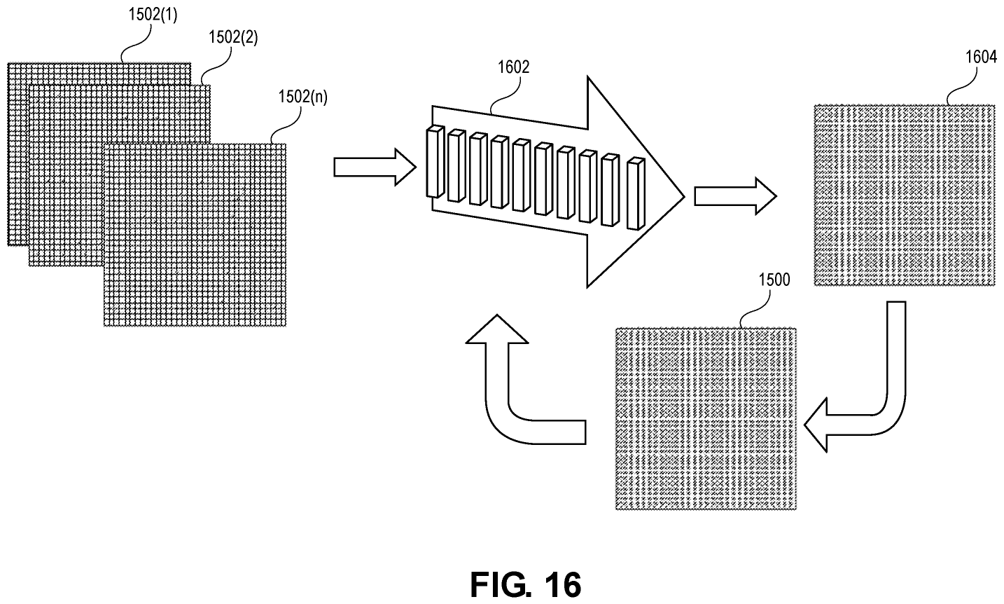

Returning to FIG. 12, the machine learning model (e.g., neural network (NN)) may then be trained, as at 1208. For example, as shown in FIG. 16, the decimated baseline dataset 1502(1), 1502(2), . . . , 1502(n) may be inputted into a NN 1602. The output of the NN 1602 is a reconstructed complete dataset 1604 with sources and receivers distributed along the grid, as discussed above. The difference between the reconstructed dense dataset 1604 and the ground truth (the original dense baseline dataset 1500), i.e., the residual, is used to construct a loss function to be back-propagated to the NN 1602 to update parameters or weights of the NN 1602 and thereby increase the confidence/accuracy of the NN 1602. This procedure may be repeated until the NN 1602 is trained (e.g., until a loss function value is reduced to a certain level, or until the loss function value does not decrease anymore).

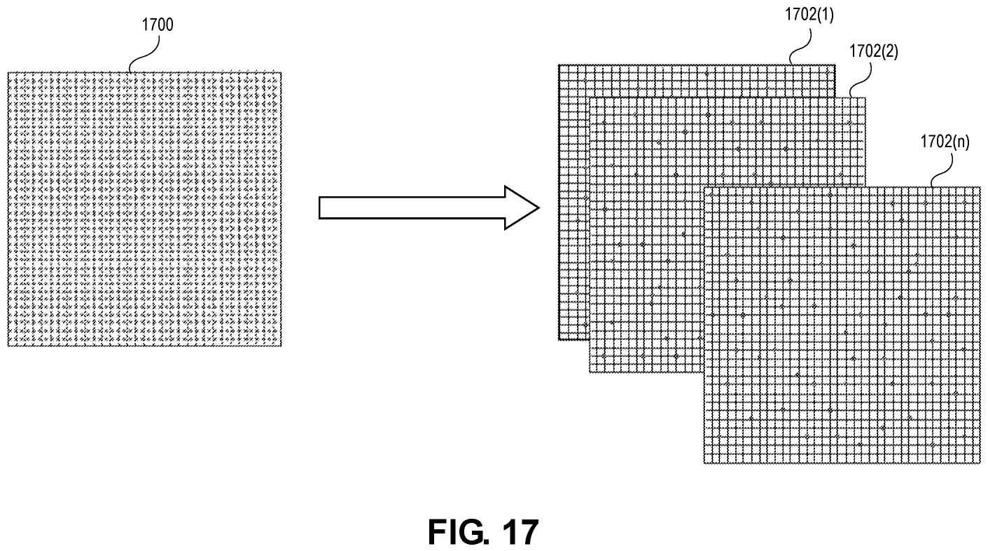

In FIG. 12, the dense monitoring dataset may then be decimated, e.g., by removing one or more sources, receivers, or both therefrom, as at 1210. This may proceed similarly to the baseline dataset. For example, as shown in FIG. 17, the “regularized” (i.e., receivers/sources shifted to a grid, as discussed above) monitoring dataset 1700 may be used to generate several sparse monitoring datasets 1702(1), 1702(2), . . . , 1702(n) by removing one or more sources/receivers from the monitoring dataset 1700 (e.g., randomly or using some predesigned source/receiver dropping schemes). For example, the number of sources/receivers in the monitoring dataset 1700 may be reduced, e.g., to a predetermined number of sources/receivers desired to be included in a survey. In at least some embodiments, the number of sources/receivers may be dynamically determined, e.g., reduced until the machine learning model is not able to produce accurate predictions.

In some circumstances, there may be no dense monitoring dataset available as input at 1202 in FIG. 12. Accordingly, the dense baseline dataset may be employed for survey design. In other words, the training dataset and the testing/implementation dataset may be the same, that is, the baseline dataset. In this case, block 1210 of FIG. 12 might be omitted.

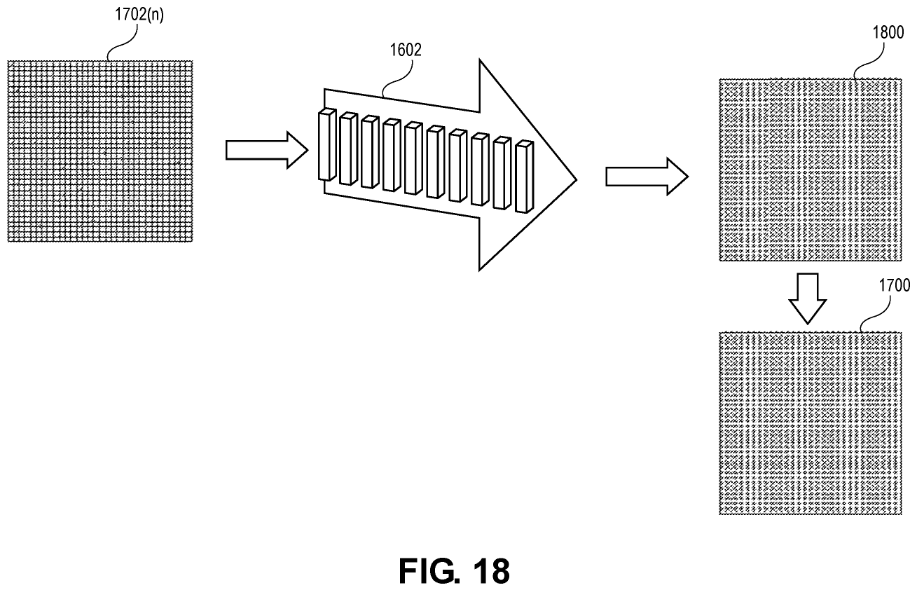

Returning to FIG. 12, the machine learning model (e.g., neural network) may then be used to predict an accuracy of the dense (monitoring or baseline) dataset, as at 1211. As noted above, in some cases, a dense monitoring dataset may not be available, and thus the dense dataset may be the dense baseline dataset. As shown schematically in FIG. 18, one of the sparse monitoring datasets 1702(n) (obtained at 1210 of FIG. 12) may be fed into the fully trained NN 1602 to reconstruct a dense monitoring dataset 1800 based thereon. This reconstructed monitoring dataset 1800 may be compared with the ground truth (i.e., the original dense monitoring dataset 1700 or the dense baseline dataset 1500) to evaluate the prediction accuracy of the NN 1602. This procedure may be applied to each sparse monitoring dataset 1702(1), 1702(2), . . . , 1702(n) generated at 1210 of FIG. 12, or any subset thereof.

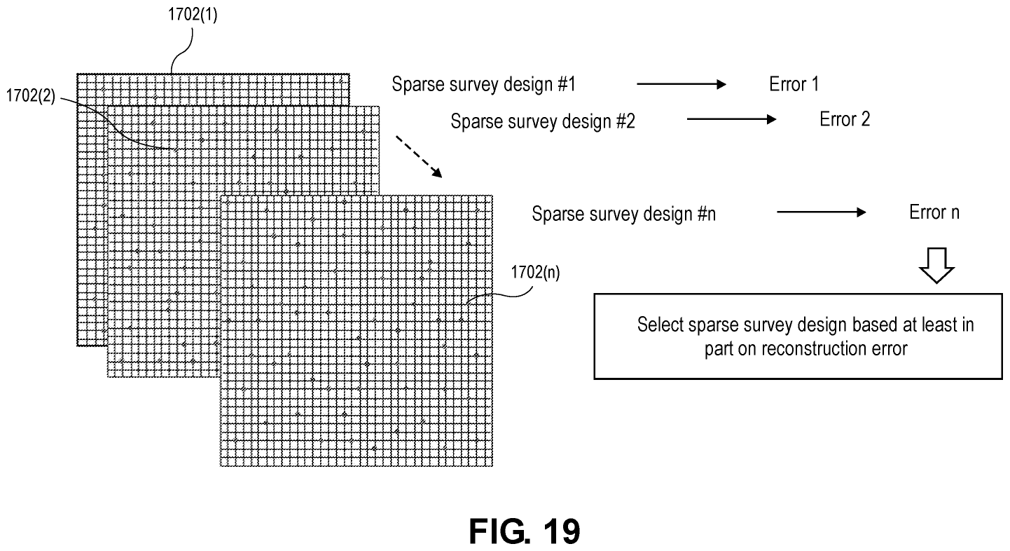

Referring again to FIG. 12, a sparse survey design may then be selected, e.g., based on accuracy, for a recommendation, as at 1212. For example, referring to FIG. 18, the sparse monitoring dataset 1702(n) may be run through the NN 1602, such that the reconstructed dataset 1800 is produced, and the accuracy thereof calculated. Accordingly, referring now to FIG. 19, each of the sparse monitoring datasets 1702(1), 1702(2), . . . , 1702(n) may have a rate of error (or, similarly, an accuracy) associated therewith. A survey design may then be recommended and/or selected based on one or more of the sparse monitoring datasets 1702(1), 1702(2), . . . , 1702(n) that have the least error, or an acceptable error, in some embodiments, along with other factors that may weigh in to the selection.

In some embodiments, this recommendation of one or more of the sparse survey design may be displayed to an operator as a visual depiction of and/or implemented by physical arrangement of one or more components of a physical survey system, e.g., placing the sources/receivers at particular locations. The survey design may then be employed and implemented in order to collect data for a CO2 injection project, or any other type of oilfield project.

FIG. 20 illustrates a flowchart of a method 2000 for seismic surveying, specifically sparse monitoring data reconstruction within a seismic survey operation, according to an embodiment. The method 2000 may include receiving a baseline dataset and a sparse monitoring data set, as at 2002. The baseline dataset may be relatively dense (e.g., include more sources/receivers per unit area) than the sparse monitoring data.

The method 2000 may then include preprocessing the datasets, e.g., shifting the baseline dataset and/or the monitoring dataset such that the source and receiver geometries in both datasets match one another, as at 2004. This may be performed by shifting the receivers/sources to a grid, as discussed above, or any other manner of regularization, so as to facilitate comparison of source/receiver data between the two datasets.

The method 2000 may include generating an output image that is the same size as the monitoring dataset from the baseline dataset, as at 2006. That is, the output image may be based on a reduced density of sources/receivers.

The method 2000 may include generating a selected output by removing traces from the output image based on a selection matrix, as at 2008. The selection matrix may be configured to remove traces that are not seen in the monitoring datasets, but were present in the baseline dataset. Next, the selected traces in the output image may be compared with the corresponding traces in the (relatively sparse) monitoring data. This comparison indicates an accuracy by which the machine learning model is able to predict the measured monitoring data based on baseline data. A loss function may be generated based on this comparison, with the loss function mathematically representing the difference determined by the comparison, as at 2010. Thus, the machine learning model is built to predict what the measured monitoring data would have included, e.g., what the monitoring dataset image would show, if it was not missing the traces.

This process may be repeated one or more (e.g., many) times to train the machine learning model to reconstruct measured monitoring data that is missing traces. For example, multiple different portions (e.g., images) from the baseline dataset may be fed to the machine learning model, and the loss function resulting therefrom may be employed to adjust the parameters (e.g., weights) of the machine learning model, in order to increase the accuracy of the predictions made by the machine learning model, as at 2012. Accordingly, the same baseline data, but different portions thereof, is used to generate incomplete monitoring data. In at least some embodiments, the reconstructed monitoring datasets generated by the method 2000 may be employed for generating the sparse monitoring datasets of the method 400 of FIG. 4.

Thus, embodiments of the method 2000 may employ the functions specific to the computing device to enhance images thereof, and thereby permit the selection of sparse monitoring surveys that may reduce equipment and labor expenses in selecting and deploying hardware for collecting surveys in a given area of interest.

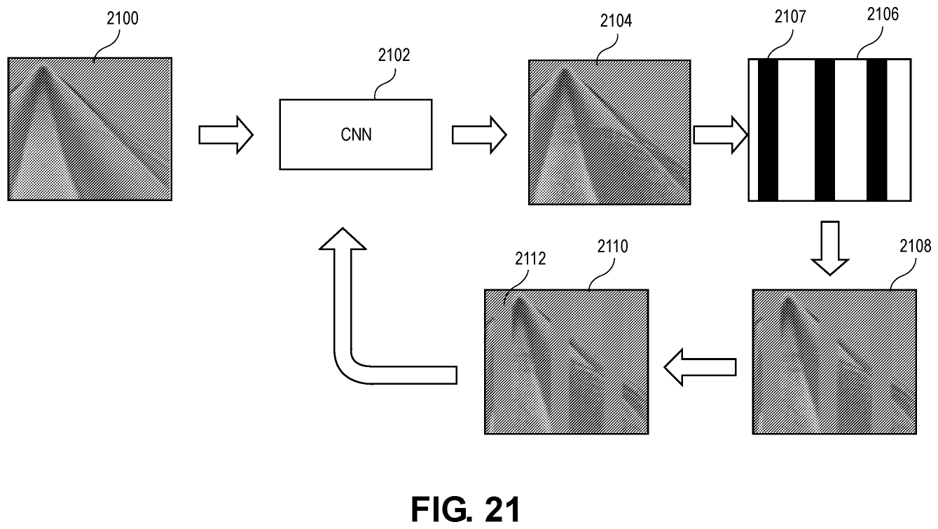

FIG. 21 illustrates a schematic view that depicts the stages of the method 2000 just described, according to an embodiment. As discussed above, a dense baseline data set 2100 is fed to a machine learning model (e.g., a convolutional neural network (CNN) 2102), which generates an output image 2104 of the same data size as the (relatively sparse) measured data. Next, a selection matrix 2106 is applied to the output image 2104, with muted areas 2107 representing areas where traces are to be removed, resulting in the selected output 2108. The selected output 2108 is then compared to a measured monitoring dataset 2110 representing the same image, and missing traces (blank areas 2112) corresponding to the muted areas 2107. The comparison may be used to define a loss function, which may then be fed back to the CNN 2102 and used to adjust the parameters/weights of the CNN 2102 and thereby increase the confidence and accuracy of the predictions by the CNN 2102.

In one or more embodiments, the functions described can be implemented in hardware, software, firmware, or any combination thereof. For a software implementation, the techniques described herein can be implemented with modules (e.g., procedures, functions, subprograms, programs, routines, subroutines, modules, software packages, classes, and so on) that perform the functions described herein. A module can be coupled to another module or a hardware circuit by passing and/or receiving information, data, arguments, parameters, or memory contents. Information, arguments, parameters, data, or the like can be passed, forwarded, or transmitted using any suitable means including memory sharing, message passing, token passing, network transmission, and the like. The software codes can be stored in memory units and executed by processors. The memory unit can be implemented within the processor or external to the processor, in which case it can be communicatively coupled to the processor via various means as is known in the art.

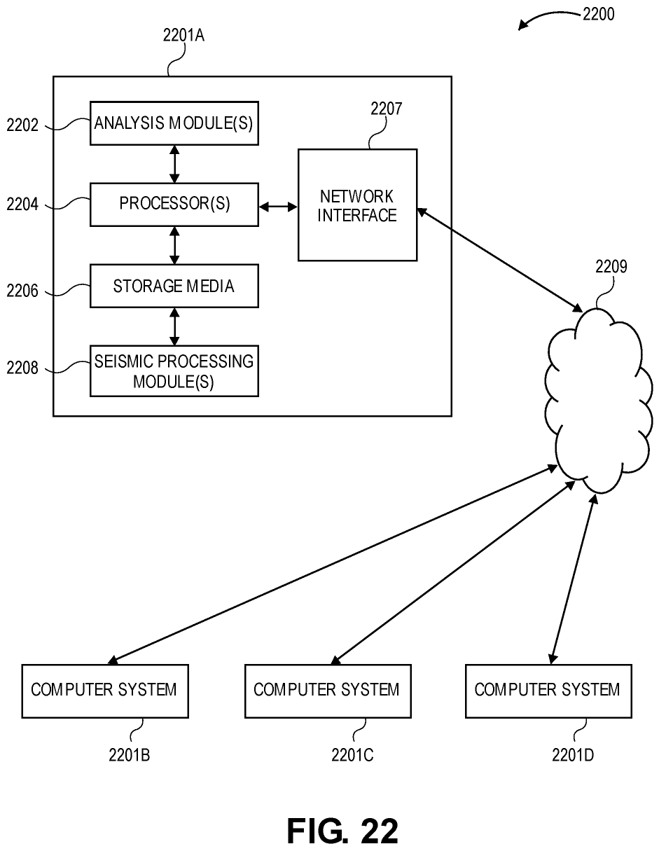

In some embodiments, any of the methods of the present disclosure may be executed by a computing system. FIG. 22 illustrates an example of such a computing system 2200, in accordance with some embodiments. The computing system 2200 may include a computer or computer system 2201A, which may be an individual computer system 2201A or an arrangement of distributed computer systems. The computer system 2201A includes one or more analysis module(s) 2202 configured to perform various tasks according to some embodiments, such as one or more methods disclosed herein. To perform these various tasks, the analysis module 2202 executes independently, or in coordination with, one or more processors 2204, which is (or are) connected to one or more storage media 2206. The processor(s) 2204 is (or are) also connected to a network interface 2207 to allow the computer system 2201A to communicate over a data network 2209 with one or more additional computer systems and/or computing systems, such as 2201B, 2201C, and/or 2201D (note that computer systems 2201B, 2201C and/or 2201D may or may not share the same architecture as computer system 2201A, and may be located in different physical locations, e.g., computer systems 2201A and 2201B may be located in a processing facility, while in communication with one or more computer systems such as 2201C and/or 2201D that are located in one or more data centers, and/or located in varying countries on different continents).

A processor can include a microprocessor, microcontroller, processor module or subsystem, programmable integrated circuit, programmable gate array, or another control or computing device.

The storage media 2206 can be implemented as one or more computer-readable or machine-readable storage media. Note that while in the example embodiment of FIG. 22 storage media 2206 is depicted as within computer system 2201A, in some embodiments, storage media 2206 may be distributed within and/or across multiple internal and/or external enclosures of computing system 2201A and/or additional computing systems. Storage media 2206 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above can be provided on one computer-readable or machine-readable storage medium, or alternatively, can be provided on multiple computer-readable or machine-readable storage media distributed in a large system having possibly plural nodes. Such computer-readable or machine-readable storage medium or media is (are) considered to be part of an article (or article of manufacture). An article or article of manufacture can refer to any manufactured single component or multiple components. The storage medium or media can be located either in the machine running the machine-readable instructions, or located at a remote site from which machine-readable instructions can be downloaded over a network for execution.

In some embodiments, computing system 2200 contains one or more seismic processing module(s) 2208. In the example of computing system 2200, computer system 2201A includes the seismic processing module 2208. In some embodiments, a single seismic processing module may be used to perform some or all aspects of one or more embodiments of the methods. In alternate embodiments, a plurality of seismic processing modules may be used to perform some or all aspects of methods.

It should be appreciated that computing system 2200 is only one example of a computing system, and that computing system 2200 may have more or fewer components than shown, may combine additional components not depicted in the example embodiment of FIG. 22, and/or computing system 2200 may have a different configuration or arrangement of the components depicted in FIG. 22. The various components shown in FIG. 22 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are all included within the scope of protection of the invention.

Geologic interpretations, models and/or other interpretation aids may be refined in an iterative fashion; this concept is applicable to embodiments of the present methods discussed herein. This can include use of feedback loops executed on an algorithmic basis, such as at a computing device (e.g., computing system 2200, FIG. 22), and/or through manual control by a user who may make determinations regarding whether a given step, action, template, model, or set of curves has become sufficiently accurate for the evaluation of the subsurface three-dimensional geologic formation under consideration.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. Moreover, the order in which the elements of the methods are illustrated and described may be re-arranged, and/or two or more elements may occur simultaneously. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A method for seismic surveying, the method comprising:
receiving a baseline dataset and a plurality of sparse monitoring datasets;
generating a decimated baseline dataset by removing one or more sources, receivers, or both from the baseline dataset;
generating a reconstructed baseline dataset by inputting the decimated baseline dataset into a machine learning model;
generating reconstructed monitoring datasets by inputting the plurality of sparse monitoring datasets to the machine learning model, wherein the machine learning model was trained based on a comparison of the reconstructed baseline dataset to the baseline seismic dataset;
determining accuracies for the plurality of sparse monitoring datasets by comparing the reconstructed monitoring datasets to the baseline dataset; and
selecting one or more survey geometries for arranging physical sources and physical receivers in a seismic survey based at least in part on the accuracies of the plurality of sparse monitoring datasets.

2. The method of claim 1, further comprising arranging sources and receivers in a field based on the selected one or more survey geometries.

3. The method of claim 1, wherein the baseline dataset is denser than individual sparse monitoring datasets of the plurality of sparse monitoring datasets, and wherein generating the decimated baseline datasets comprises reducing the density of the baseline dataset to equal the density of the individual sparse monitoring datasets.

4. The method of claim 1, further comprising:
shifting locations of receivers, sources, or both represented in the plurality of sparse monitoring datasets to correspond to a grid; and
shifting locations of the receivers, sources, or both of the baseline dataset to correspond to the grid.

5. The method of claim 1, further comprising:
generating decimated monitoring datasets by removing one or more sources, one or more receivers, or both from at least one of the plurality of sparse monitoring datasets; and
generating reconstructed sparse monitoring datasets by feeding the decimated monitoring datasets to the machine learning model.

6. The method of claim 1, wherein the machine learning model comprises a convolutional neural network.

7. A method for seismic surveying, the method comprising:
receiving a baseline dataset and a monitoring dataset;
generating an output image based on the baseline dataset using a machine learning model;
generating a selected output by removing one or more traces from the output image;
determining a loss function by comparing the selected output with the monitoring dataset;
adjusting the machine learning model based at least in part on the loss function; and
reconstructing an interpolated monitoring dataset based on the monitoring dataset using the machine learning model.

8. The method of claim 7, wherein the output image has a same size as the monitoring dataset.

9. The method of claim 7, wherein the one or more traces that are removed correspond to one or more traces that are included in the baseline dataset but are not included in the monitoring dataset.

10. The method of claim 7, further comprising generating a seismic image based at least in part on the monitoring dataset and visualizing the seismic image on a display.

11. The method of claim 7, wherein generating the selected output comprises applying a selection matrix with one or more muted portions to the output image.

12. The method of claim 11, wherein the muted portions correspond to the one or more traces that are removed.

13. A method for seismic surveying, the method comprising:
receiving a monitoring dataset and a baseline dataset;
reconstructing an interpolated monitoring dataset based on the monitoring dataset using a first machine learning model, wherein reconstructing comprises:
generating an output based on the baseline dataset;
generating a selected output by removing one or more traces from the output;
adjusting the first machine learning model based at least in part on the selected output; and
selecting one or more survey geometries for arranging physical sources and physical receivers in a seismic survey based at least in part on the interpolated monitoring dataset that was reconstructed and accuracies associated with the plurality of sparse monitoring datasets, wherein selecting includes:
generating a decimated baseline dataset by removing one or more sources, receivers, or both from the baseline dataset;
generating reconstructed monitoring datasets by inputting the plurality of sparse monitoring datasets to a second machine learning model; and
comparing the reconstructed monitoring datasets to the baseline dataset.

14. The method of claim 13, wherein selecting the one or more survey geometries further includes generating the plurality of sparse monitoring datasets based at least in part on the interpolated monitoring dataset that was reconstructed.

15. The method of claim 13, further comprising arranging sources and receivers in a field based on the selected one or more survey geometries.

16. The method of claim 13, wherein the baseline dataset is denser than individual sparse monitoring datasets of the plurality of sparse monitoring datasets, and wherein generating the decimated baseline dataset comprises reducing the density of the baseline dataset to equal the density of the individual sparse monitoring datasets.

17. The method of claim 13, further comprising shifting locations of receivers, sources, or both represented in the plurality of sparse monitoring datasets to correspond to a grid, and shifting locations of the receivers, sources, or both of the baseline dataset to correspond to the grid.

18. The method of claim 13, further comprising:
generating decimated monitoring datasets by removing one or more sources, one or more receivers, or both from at least one of the plurality of sparse monitoring datasets; and
generating reconstructed sparse monitoring datasets by feeding the decimated monitoring datasets to the second machine learning model.

19. The method of claim 13, wherein the first machine learning model, the second machine learning model, or both comprises one or more convolutional neural networks.

20. The method of claim 13, wherein the output has a same size as the monitoring dataset.

21. The method of claim 13, wherein the one or more traces that are removed correspond to one or more traces that are included in the baseline dataset but are not included in the monitoring dataset.

22. The method of claim 13, further comprising generating a seismic image based at least in part on the monitoring dataset and visualizing the seismic image on a display.

23. The method of claim 13, wherein generating the selected output comprises applying a selection matrix with one or more muted portions to the output.

24. The method of claim 23, wherein the one or more muted portions correspond to the one or more traces that are removed.
